(19) United States
(12) Patent Application Publication
(10) Pub. No.: US 2013/0141933 A1
(43) Pub. Date: Jun. 6, 2013

(54) PIVOTABLE LED LIGHTING APPARATUS AND UNIVERSAL MOUNTING ASSEMBLY AND METHOD

(71) Applicants: LUIS LEONARDO, Walnut Creek, CA (US); Oscar Aguilera, Concord, CA (US)

(72) Inventors: LUIS LEONARDO, Walnut Creek, CA (US); Oscar Aguilera, Concord, CA (US)

(73) Assignee: NOVA SPORT LIGHTS, LLC

(21) Appl. No.: 13/312,026

(22) Filed: Dec. 6, 2011

(51) Int. Cl. F21V 21/30; H05K 13/04; F21L 4/08

(52) U.S. Cl. 362/523; 362/183; 29/592

(57) ABSTRACT

A lighting apparatus usable with a mobile vehicle, which includes first and second housings which contain the power source, the switch mechanism and the light emitting elements therein. A pivoting mechanism allows relative pivotal movement between the two housings thereby allowing the user to manipulate the desired emission angle of illumination. The pivoting mechanism also permits electrical communication between the power source (rechargeable batteries) and the light emitting elements. The lighting apparatus includes an integral charging port for recharging the batteries, such as a micro USB port. The lighting apparatus is adapted to the mobile vehicle by a universal mounting assembly which is configured to be interchangeably attached and detached to fit on different configurations on a particular vehicle. The mounting assembly comprises of a rigid assembly, which attaches the lighting apparatus to the mounting assembly with a flexible fastener to attach the mount to the vehicle.

### BACKGROUND OF THE INVENTION

The present invention relates generally to a lighting apparatus and mounting assembly for mobile vehicles, and more particularly to a pivotable light apparatus with light emitting diodes (LEDs), integral USB charger and universal mounting assembly which is mountable in various configurations of a mobile vehicle including the method of illuminating, making and operating the same.

The primary purpose of a light assembly on mobile vehicles such as bicycles is to provide illumination and conspicuity for the cyclist. Light assemblies aid the cyclist in seeing the road ahead of them at times of day and night when there is not enough ambient light to safely ride a bicycle and also allow the cyclist to be seen by oncoming motorists.

In the prior art, light assemblies have used a single beam of light, which limited the field of vision due to the small size of the single beam of light. For cyclists riding at night, particularly at higher speeds, it is advantageous to have more light and a wider-angle beam than that of a single beam.

Another disadvantage of the prior art was the difficulty of charging the power supply to the light assembly. The cyclist would have to carry spare batteries as a backup in case of power loss.

Another important feature in light assemblies is the ease with which the apparatus can be mounted and dismounted on a mobile vehicle, such as a bicycle. This is often necessary when a cyclist has two or more bicycles and does not want to purchase a dedicated light for each bike or if the cyclist wants to remove only the light assembly from the bike for example due to fear of theft of the light assembly.

Therefore it is desirable to provide a pivotable LED light apparatus with light emitting diodes, integral battery charger and a universal mounting assembly which is mountable in various configurations of a mobile vehicle, as provided by the present invention.

### SUMMARY OF THE INVENTION

The present invention provides a lighting apparatus usable with a mobile vehicle such as a bicycle. In one embodiment, the lighting apparatus includes a first housing, which includes a power source such as rechargeable batteries and a switch mechanism. A second housing is also included which is comprised of light emitting elements such as LEDs. The advantages of LEDs are their smaller size and weight, increased power efficiency, durability, longer life and instant on-off capability. The limitation is that the LEDs provide stationary beams and the cyclist could not easily manipulate the emitting angle of the resultant beam. However, the housings in the present invention are connected by a pivoting mechanism, which allows relative movement between the two housings and permits electrical communication between the light emitting diodes and the batteries. The pivoting mechanism allows the lighting apparatus to provide illumination at different emission angles. The switch mechanism further allows for multiple configurations of the LEDs. The LEDs may be selected to all turn on; all turn off, turn on in a predesignated configuration or turn on in a sequential or nonsequential flashing mode.

The first housing also includes an integral charging port in order to recharge the batteries. The USB charger is integrated into the unit, and therefore obviates the need to externally couple the charger with the light assembly in order to charge the batteries.

According to one aspect of the present invention, the lighting apparatus is adapted to a universal mounting assembly. The mounting assembly may be interchangeably attached and detached on different bicycles or on different mounting positions on a particular bike. In the prior art, one disadvantage was that each mount was specific to one specific diameter of handlebar due to the fastener assembly. The problem was that the mount was not adaptable to be used in different configurations: on the top or bottom of the handlebars or on the stem. The mounting assembly of the present invention comprises of a polymeric fastener, such as a TPE or rubber strap for example. In one embodiment, various sizes of straps are provided in order to properly fit various sizes of bicycle stems and handlebars. Alternatively, the fastener can be a universal strap with cutouts in preconfigured locations to allow the mounting assembly to be sized to fit various configurations of a mobile vehicle. In the prior art, the fasteners were often cumbersome to use and required additional accessories like screwdrivers to affix the fastener to the bike. The mounting assembly of the present invention requires no additional tools and improves the ease of attaching and detatching the mounting assembly from a mobile vehicle.

In another embodiment of the present invention, a lighting apparatus is configured to be used on a mobile vehicle, which includes a first housing including a first weatherproof chamber enclosed by an upper horizontal surface, a lower horizontal surface, a rear vertical surface, a front surface, and two side surfaces; one or more rechargeable lithium ion batteries placed inside said first weatherproof chamber; a switch on the first housing that may be placed at the upper horizontal surface; an integral charging port on the first housing that may be placed at the rear vertical surface for recharging said batteries; a pedestal located on the lower horizontal surface; a second housing including a second weatherproof chamber, a front vertical surface, a rear faceted surface, and two elongated side arms extending rearward, wherein each arm has an inside face; two or more LEDs placed inside said second weatherproof chamber, each light emitting diode capable of emitting up to at least 180 lumens; wherein said switch controls electrical input from said batteries to said LEDs; a transparent window on the front vertical surface of the second housing; a pivoting mechanism that connects and allows relative pivotal movement between the first and second housings, wherein said second housing is adjustable to pivot in angles from 25 degrees vertically above to 25 degrees vertically below the horizontal axis of the lighting apparatus; and a universal mounting apparatus for detachably attaching to said pedestal and to the mobile vehicle.

In an aspect of the embodiment, the switch is a push-button switch with a weatherproof cover. In another aspect of the embodiment, the two or more LEDs are capable of operating in a mode selected from the group consisting of: all off, one LED on, two LEDs on, all LEDs on, and a flashing day time mode. In a further aspect of the embodiment, the two or more LEDs are powered on non-simultaneously in the flashing daytime mode. For example, the LEDs can light sequentially or randomly at predetermined intervals, e.g. LEDs emit light every 0.75 seconds. In a yet further aspect of the embodiment, the pedestal is adapted for attaching to the universal mounting apparatus. In another aspect, the pedestal comprises a rectangular column, a first end of said rectangular column attaches to the lower horizontal surface of the first housing, a second end of said rectangular column extends outward to form a base plate, wherein said column has a square cross section. In another variation of the embodiment, the charging port comprises a micro USB port with a flexible cover. In another aspect, the embodiment includes a means for fastening the universal mounting apparatus to the mobile vehicle. In certain aspects, the means for fastening comprises a rubber strap. In certain other aspects, the rubber strap is selected from the group consisting of a small strap, a medium strap and a large strap. In another configuration of the embodiment, the first and second housings are formed of a fusion sealed rigid material. In other aspects of the embodiment, the first housing has a substantially rectangular horizontal cross section that tapers from the front to the rear, wherein a receiving aperture is formed on the front end of each side surface, wherein the front surface has an outwardly concaved contour. In certain aspects, the two side arms of the second housing envelop the first housing, wherein there is a pivot pin on the inside face of each arm, wherein said pivot pins engage the receiving apertures on the first housing. In other aspects, the pivot pins have a hollow tubular structure for conducting electrical wires between the first housing and the second housing. In certain other aspects, a friction device is fitted over each pivot pin to maintain friction between the first and second housings, such as a torque O ring. In another aspect of the embodiment, the lighting apparatus is adapted to be used on a bicycle.

In another embodiment, a lighting apparatus configured for use on a mobile vehicle includes a universal mounting assembly for interchangeably attaching to a mobile vehicle in one or more mounting configurations. The universal mounting assembly includes a channel assembly with a substantially rectangular rigid body for engaging a pedestal, said channel assembly including: a recess at the upper surface of the channel assembly bound by a front wall, two side walls, and a bottom plane, wherein the rear of the recess is open, wherein said two side walls are perpendicular to the front wall, wherein each side wall has a rim that forms a groove inside the recess, a knob protruding on the front face of the channel assembly, two parallel raised tabs on a bottom surface of the channel assembly, a rear lower wall on the bottom surface of the channel assembly, said rear lower wall including a substantially rectangular window; a rubber strap member including a back end block, a middle strap portion, and a front-end block, wherein an elongated cutout extends from the middle strap portion to the front-end block; wherein the middle strap portion is adapted to pass through the substantially rectangular window; wherein the elongated cutout is adapted to engage with the knob on the front face of the channel assembly.

In another aspect of the embodiment, the front end block of the strap member is about the same as thick as the middle strap portion, is a little over twice as wide as the center strap portion, and has a rounded curvature on the peripheral of the front end block, and wherein the back end block is wider and thicker than the center strap portion, includes two slits on a first surface for fitting on the two parallel raised tabs on the bottom surface of the channel assembly, and is curved on a second surface for fitting on a tubular object. In certain aspects, the bottom plane includes a cutout tab formed between two parallel cutouts, said cutout tab having a raised notch at the rear opening of the recess, said cutout tab extends outside of the recess forming a finger tab.

In a further embodiment, a method of illuminating a mobile vehicle includes the steps of: providing a first housing comprising one or more lithium ion rechargeable batteries, wherein said first housing comprises an integral charging port for recharging said batteries; providing a second housing comprising two or more LEDs each capable of outputting at least 180 lumens; controlling electrical input from said batteries to said LEDs using a switch on said first housing for; and pivoting said second housing relative to said first housing a pivotal mechanism to provide illumination at different emission angles. In another aspect of the embodiment, the first housing comprises a pedestal for attaching to a mounting apparatus. In certain aspects, the embodiment further includes providing a translucent window on a forward vertical surface of the second housing. In other aspects, the first and second housings are formed of a rigid material. In certain other aspects, three LEDs are provided. In further aspects, the three LEDs are capable of being independently controlled. In another aspect of the embodiment, the switch is a push-button switch. In various aspects, the mobile vehicle is a bicycle.

In yet a further embodiment, a method of making a lighting apparatus configured for use on a mobile vehicle includes the following steps in any order: making a first housing including a first weatherproof chamber enclosed by an upper horizontal surface, a lower horizontal surface, a rear vertical surface, a front surface, and two side surfaces; installing one or more rechargeable lithium ion batteries placed inside said first weatherproof chamber; providing an integral charging port on said first housing, e.g., on the rear vertical surface capable of recharging said batteries; providing a pedestal on the lower horizontal surface; positioning a switch on the first housing, e.g., on the upper horizontal surface; making a second housing including a second weatherproof chamber and a front vertical surface; providing a transparent window on the front vertical surface of the second housing; installing two or more LEDs inside said second weatherproof chamber, each light emitting diode capable of emitting up to at least 180 lumens; connecting the first housing and the second housing via a pivoting mechanism that allows relative pivotal movement between the first and second housings, wherein said second housing is adjustable to pivot in angles from 25 degrees vertically above to 25 degrees vertically below the horizontal axis of the lighting apparatus; and providing a universal mounting apparatus for detachably attaching said pedestal and to the mobile vehicle.

In another aspect of the embodiment, the switch controls electrical input from said batteries to said diodes. In certain other aspects of the embodiment, the switch is a push on-off switch. In another variation of the embodiment, the pedestal is adapted for slidably attaching to the universal mounting apparatus. In yet another aspect, the embodiment further includes a means for fastening the universal mounting apparatus to the mobile vehicle. In a further aspect, the means for fastening comprises a polymeric strap, such as a rubber strap. In another variation of the embodiment, the rubber strap is selected from the group consisting of a small strap, a medium strap and a large strap. In other aspects of the embodiment, the first and second housings are formed of a fusion sealed rigid material. In other configurations of the embodiments, the pivoting mechanism comprises a friction device, such as a torque O-ring to maintain the second housing at a predetermined configuration. In a further aspect of the embodiment, the three LEDs are capable of operating sequentially. In a yet further aspect, the method includes a flashing daytime mode capable of emitting 180 lumens every 0.75 seconds. In various aspects, the lighting apparatus is adapted to be used on a bicycle.

According to another embodiment, a method of operating a lighting apparatus includes the following steps: charging the lighting apparatus, wherein said lighting apparatus includes a first housing including the electrical switch, one or more rechargeable batteries, and a charging outlet, a second housing including two or more LEDs, and a pivot mechanism connecting the first housing and the second housing and allowing the first housing to pivot against the second housing, wherein at least one of said LEDs is equipped with a narrow angle beam reflector, and at least one of said LEDs is equipped with a wide angle beam reflector; turning on said light apparatus by actuating an electrical switch causing electrical power to be supplied to all of one or more LED to output light with a total light output of up to 540 lumens or more. Depending on the specification of the wide angle beam reflector, lighting pattern from said mobile device can create a wide angle beam wherein said angle is at least 30 degrees from the centerline of said one or more LED.

According to another aspect, the embodiment includes actuating said electrical switch so that only one of said LED emits light. In another aspect, actuating said electrical switch causes only two of said LED to emit light. In a further aspect, actuating said electrical switch causes the LEDs to emit light sequentially, one at a time, or two or more at a time. In a yet further aspect, the electrical switch is a push-button switch that is actuated by pushing the button to the desired configuration. In another aspect, the embodiment includes pivoting said second housing relative to said first housing up or down up to 25 degrees each direction. In yet another aspect, the embodiment includes attaching a universal mounting apparatus to a mobile vehicle, and attaching said lighting apparatus to said universal mounting apparatus.

In a further embodiment, a lighting apparatus configured for use on a mobile vehicle, comprises a first weatherproof housing including an electrical switch, one or more rechargeable batteries, and a charging outlet; a second weatherproof housing including more than one LED, wherein at least one of said LED is equipped with a narrow angle beam reflector, at least one of said LED is equipped with a wide angle beam reflector, and the combined light output capacity of the LED is at least 500 lumen; and a weatherproof pivot mechanism that connects the first housing and the second housing and allows the first housing to pivot against the second housing.

In another aspect of the embodiment, the lighting apparatus includes an electrical circuit so configured that by actuating said electrical switch the LED operate in various modes including: only one of said LED emits light, only two of said LEDs emit light, and all of said LEDs emit light at the same time. In yet another aspect of the embodiment, the lighting apparatus includes an electrical circuit so configured that by actuating said electrical switch the LED emits light sequentially. In a further aspect of the embodiment, the electrical switch is a push-button switch. In a yet further aspect of the embodiment, the pivot mechanism allows said second housing pivot relative to said first housing up or down up to 25 degrees in each direction. In another variation of the embodiment, the lighting apparatus further includes a universal mounting apparatus for attaching said lighting apparatus to a mobile vehicle. In yet another variation of the embodiment, the light apparatus is made to be used on a bicycle.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

FIG. 1 illustrates a perspective side view of the lighting apparatus.

FIG. 2 illustrates a perspective rear view of the lighting apparatus.

FIG. 3 illustrates a perspective rear view of the universal mounting assembly.

FIG. 4 illustrates a perspective side view of the universal mounting assembly.

FIG. 5 illustrates a perspective front view of the universal mounting assembly.

FIG. 6 is a flow chart for a method of illuminating a mobile vehicle.

FIG. 7 is a flow chart for a method of making a lighting apparatus.

FIG. 8 is a flow chart for a method of operating a lighting apparatus.

FIG. 9 illustrates a perspective view from above showing the light emitting diodes including a narrow angle beam reflector and two wide-angle beam reflectors. The pivoting mechanism is also shown.

### DETAILED DESCRIPTION OF THE INVENTION

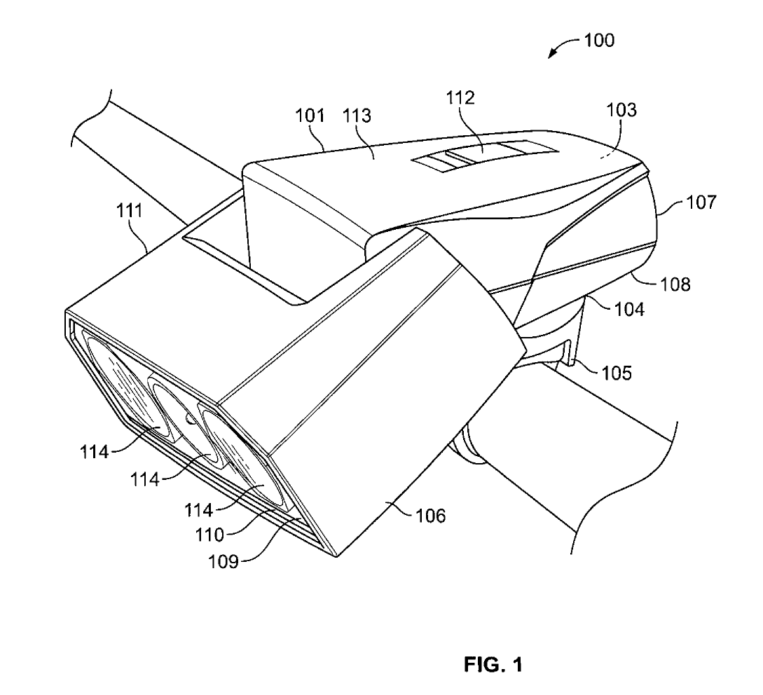

FIG. 1 shows one embodiment of the lighting apparatus (100) including a first housing 101 which houses rechargeable batteries, such as Li Ion batteries (not shown), and an integral charging port with a flexible cover 103 on a rear vertical surface 107 capable of recharging the batteries. A pedestal 104 is located on a lower horizontal surface 108, for attaching to a universal mounting apparatus 105. A second housing 106 is shown consisting of three 180 lumen light emitting diodes 114 (capable of emitting 180, 360 and 540 lumens), encased in a transparent window 109 on a forward vertical surface 110 and a pivoting mechanism 111 which allows relative pivotal movement between the first and second housings. The pivoting mechanism provides a maximum pivoting angle of 25 degrees vertically above and below the horizontal axis thereby allowing the user to select the desired emission angle of the light. A switch mechanism 112 on an upper horizontal surface 113 provides electrical input from said battery to said diodes, whereby illumination is provided.

In another aspect of the embodiment, the lighting apparatus is provided wherein the pedestal 104 comprises a slidable member on the lower horizontal surface 108 of the first housing. In other various aspects of the embodiment the slidable member of the pedestal 104 attaches to the mounting apparatus 105 to form a lighting apparatus assembly on a mobile device. In other certain aspects, the illuminated mobile device is a bicycle (not shown).

In another aspect of the embodiment, the lighting apparatus is provided wherein the mounting apparatus 105 further comprises a means for fastening (not shown) the mounting apparatus 105 to a mobile vehicle (not shown). In other various aspects of the embodiment, the means for fastening the mounting apparatus to the mobile device is a rubber strap coupled on a first end to a formed seat and on a second end to a formed tab. In certain aspects the rubber strap means for fastening and the slideable member means for fastening create a universal mounting device to the mobile device. In certain aspects the mobile device is a vehicle. In other various aspects the vehicle is a bicycle.

In another aspect of the embodiment, the lighting apparatus 100 is provided wherein the first 101 and second 106 housings are formed of a fusion sealed rigid material. In other various aspects of the embodiment, wherein the three LEDs 114 operate sequentially to provide varied light output. In another aspect of the embodiment, the switch mechanism 112 is a push on-off switch.

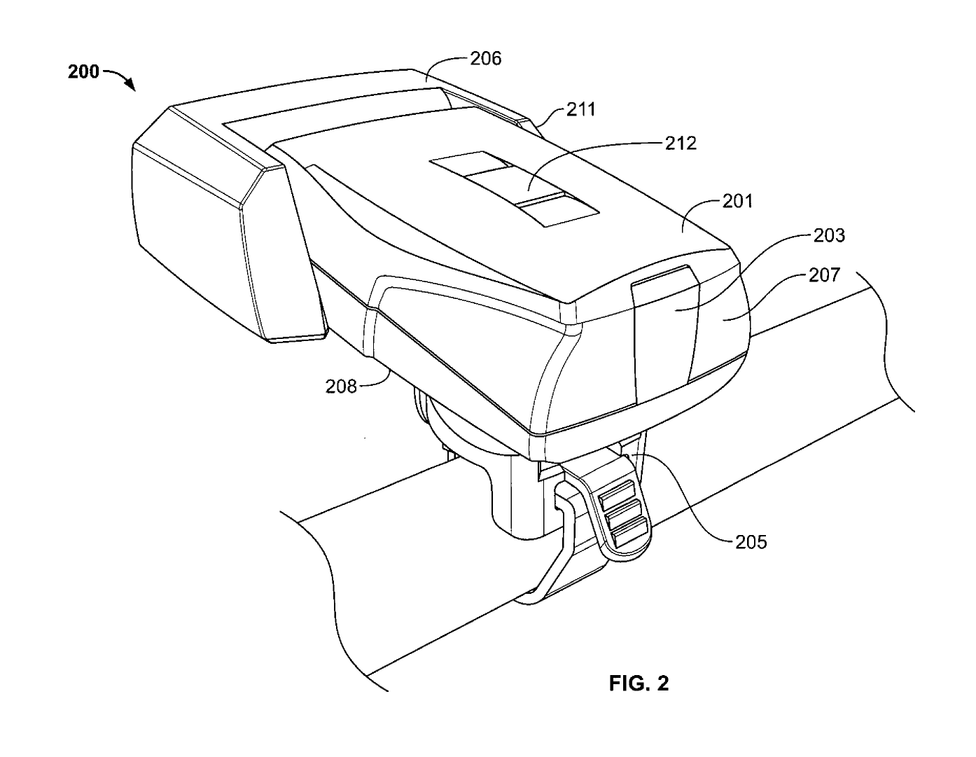

FIG. 2 shows the rear perspective view of the lighting apparatus (200) having a first housing 201, connected to the second housing 206 by a pivoting mechanism 211. The first housing includes an integral charging port 203 on the rear vertical surface 207 and a switch 212. A universal mounting apparatus 205 is shown on the lower horizontal surface 208 of the first housing 201.

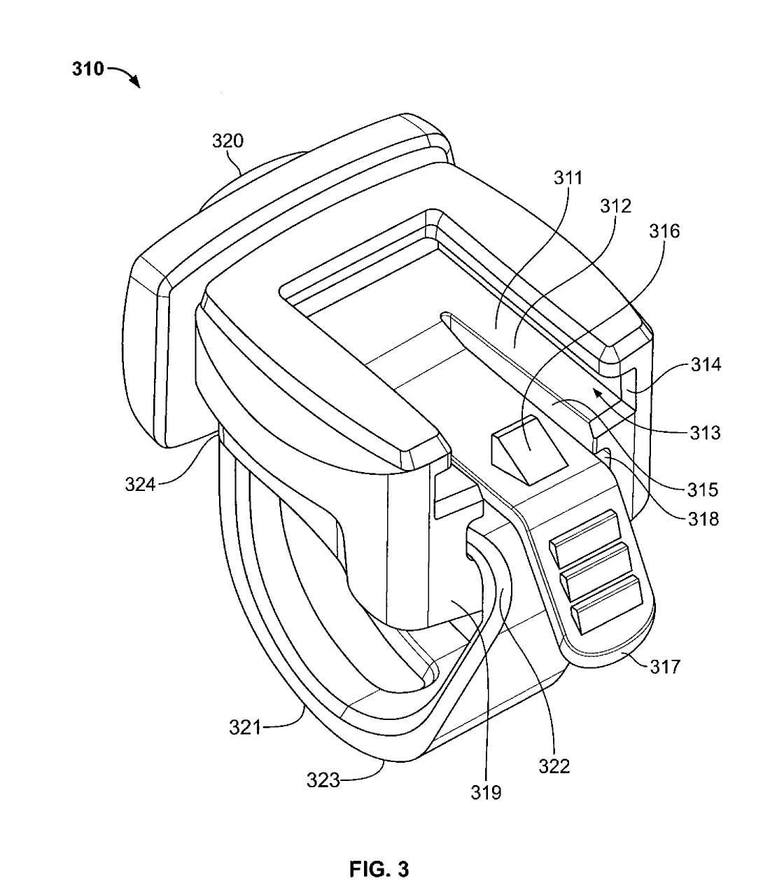

In another embodiment as shown in FIG. 3, a universal mounting assembly 310 is configured to a lighting apparatus (not shown) which is capable of being attached in one or more mobile device mounting configurations. In certain aspects of the embodiment, the universal mounting assembly 310 includes a channel assembly 311 capable of being rigidly coupled to a pedestal (not shown) of the lighting apparatus, wherein the pedestal slidably engages with a recess 312 in the channel assembly 311. The recess 312 includes a bottom plane 313, and a rear face 314 which is open. The bottom plane 313 includes a cutout tab 315 formed between two parallel cutouts, said cutout tab having a raised notch 316 at the rear opening of the recess 312, said cutout tab extends outside of the recess forming a finger tab 317. The channel assembly 311 includes a rear wall 319 having a cutout window 318 to engage a fastening means, such as a rubber strap member 321. The rubber strap member 321 includes a first rubber strap end tab 322, a middle strap portion 323 and a second rubber strap end cover 324. wherein an elongated cutout extends from the middle strap portion 323 to the front-end block; wherein the middle strap portion 323 is adapted to pass through the substantially rectangular window 318 and wherein the elongated cutout is adapted to engage with a knob 320 on the front face of the channel assembly. In yet another aspect of the embodiment, the rubber strap is designed to accommodate various lengths and diameters, for example, small, medium, and large

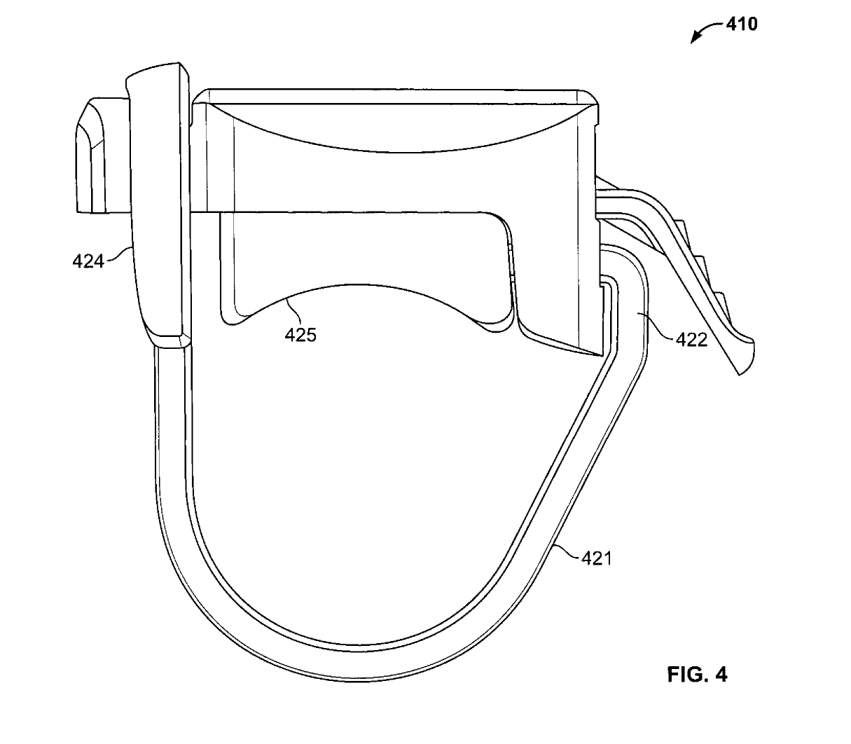

FIG. 4 shows a side view of the universal mounting apparatus 410, including a rubber strap member 421 having a first end 422 and a second end 424. The first end 422 is engaged with the cutout window (not shown) at the rear wall of the universal mounting apparatus 410. In one aspect of the embodiment, the front end of the rubber strap member 422 has a rounded curvature 425, for fitting on a tubular object, such as a handlebar or stem of a mobile vehicle.

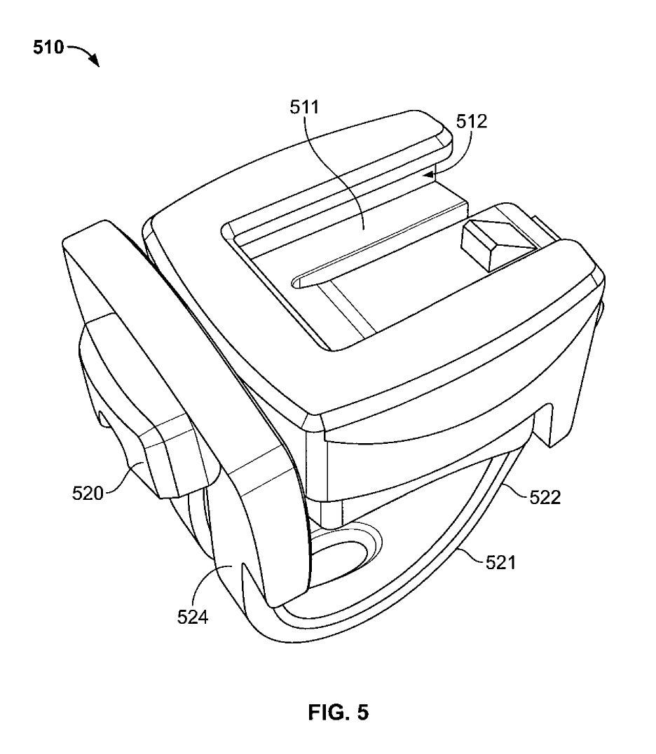

FIG. 5 shows another side view of the universal mounting apparatus 510 having a channel assembly with a recess 512 for engaging a pedestal (not shown). The mounting apparatus 510 includes a rubber strap member 521 with a first rubber strap end 522 and a second rubber strap end cover 524 which engages with the knob 520 to attach the mounting assembly to the mobile vehicle.

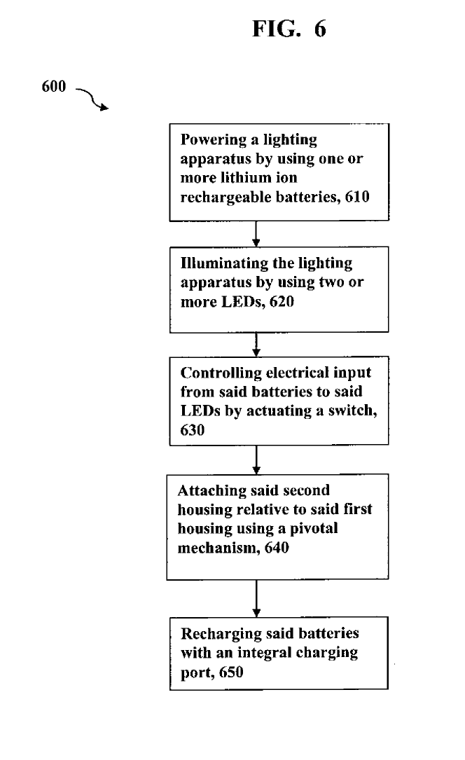

In a further embodiment, a method of illuminating a mobile vehicle 600 is shown in FIG. 6 and includes the steps of powering a lighting apparatus by using one or more lithium ion rechargeable batteries 610, wherein said first housing comprises an integral charging port for recharging said batteries; providing a second housing including two or more LEDs 620 each capable of outputting at least 180 lumens; controlling electrical input from said batteries to said LEDs actuating a switch 630 on said first housing; and pivoting said second housing relative to said first housing a pivotal mechanism 640 to provide illumination at different emission angles. Charging can be achieved by connecting an external charger to the integral charging port 650. The relative angle between the first housing and the second housing is maintained by friction between the two housings, which can be enhanced by using a friction ring. In another aspect of the embodiment, the first housing comprises a pedestal for attaching to a mounting apparatus. In certain aspects, the embodiment further includes providing a translucent window on a forward vertical surface of the second housing. In other aspects, the first and second housings are formed of a rigid material. In yet other aspects, three LEDs are provided. In a further aspect, the three LEDs are capable of being independently controlled. In another aspect of the embodiment, the switch is a push-button switch. In various aspects, the mobile vehicle is a bicycle.

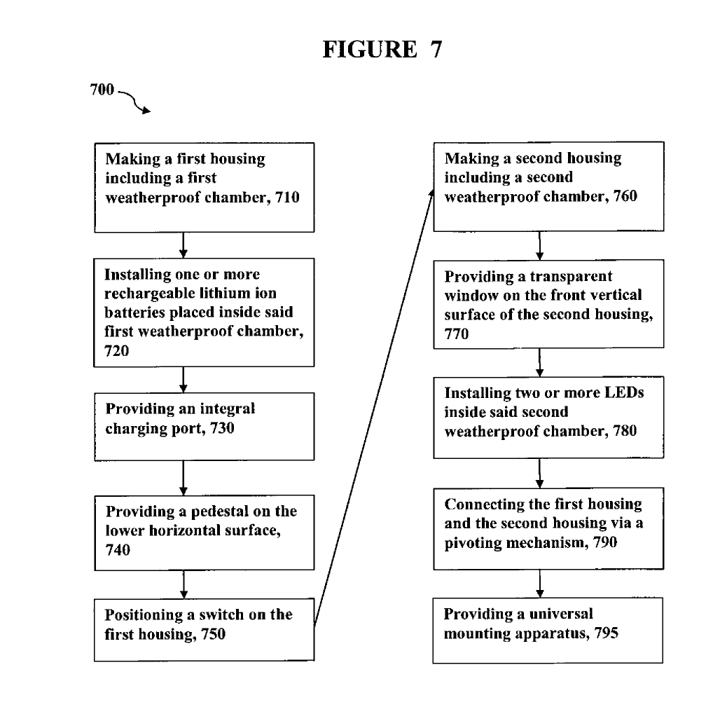

In a yet further embodiment, a method of making a lighting apparatus configured for use on a mobile vehicle 700 is shown in FIG. 7 and includes the following steps in any order: making a first housing including a first weatherproof chamber 710 enclosed by an upper horizontal surface, a lower horizontal surface, a rear vertical surface, a front surface, and two side surfaces; installing one or more rechargeable lithium ion batteries inside said first weatherproof chamber 720; providing an integral charging port 730 on said first housing, e.g., on the rear vertical surface capable of recharging said batteries; providing a pedestal on the lower horizontal surface 740; positioning a switch on the first housing 750, e.g., on the upper horizontal surface; making a second housing including a second weatherproof chamber 760 and a front vertical surface that can be flat or curved; providing a transparent window on the front vertical surface of the second housing 770 that can be flat or curved; installing two or more LEDs inside said second weatherproof chamber 780, each light emitting diode capable of emitting up to at least 180 lumens; connecting the first housing and the second housing via a pivoting mechanism 790 that allows relative pivotal movement between the first and second housings, wherein said second housing is adjustable to pivot in angles from 25 degrees vertically above to 25 degrees vertically below the horizontal axis of the lighting apparatus; and providing a universal mounting apparatus 795 for detachably attaching said pedestal to the mobile vehicle.

In another aspect of the embodiment, the switch controls electrical input from said batteries to said diodes directly or indirectly. For example, the switch sends a signal to an electronic circuit, and the electronic circuit controls the flow of electricity to the LEDs according to the signal from the switch. In certain other aspects of the embodiment, the switch is a push on-off switch. In another variation of the embodiment, the pedestal is adapted for slidably attaching to the universal mounting apparatus. In yet another aspect, the embodiment further includes a means for fastening the universal mounting apparatus to the mobile vehicle. In a further aspect, the means for fastening comprises a rubber strap. In another variation of the embodiment, the rubber strap is selected from the group consisting of a small strap, a medium strap and a large strap. In other aspects of the embodiment, the first and second housings are formed of a fusion sealed rigid material. In other configurations of the embodiments, the pivoting mechanism comprises a torque O-ring to maintain the second housing at a predetermined configuration. In a further aspect of the embodiment, the three LEDs are capable of operating sequentially. In a yet further aspect, the method includes a flashing daytime mode capable of emitting 180 lumens every 0.75 seconds. In various aspects, the lighting apparatus is adapted to be used on a bicycle.

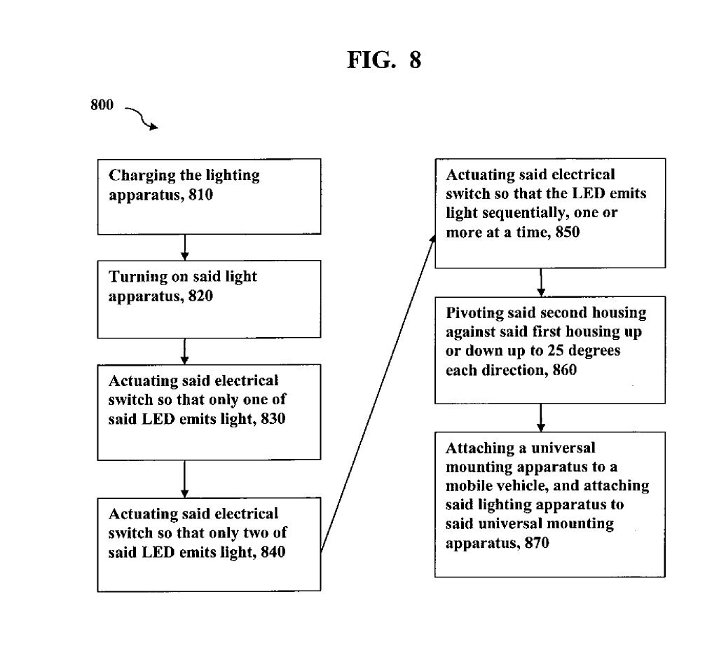

According to another embodiment, a method of operating a lighting apparatus 800, shown in FIG. 8 includes the following steps: charging the lighting apparatus 810, wherein said lighting apparatus includes a first housing including the electrical switch, one or more rechargeable batteries, and a charging outlet, a second housing including two or more LEDs, and a pivot mechanism connecting the first housing and the second housing and allowing the first housing to pivot against the second housing, wherein at least one of said LEDs is equipped with a narrow angle beam reflector, and at least one of said LEDs is equipped with a wide angle beam reflector; turning on said light apparatus 820 by actuating an electrical switch causing electrical power to be supplied to all of one or more LED to output light with a total light output of up to 540 lumens or more. Depending on the specification of the wide angle beam reflector, lighting pattern from said mobile device can create a wide angle beam wherein said angle is at least 30 degrees from the centerline of said one or more LED.

According to another aspect, the embodiment includes actuating said electrical switch so that only one of said LED emits light 830. In another aspect, the method includes actuating said electrical switch so that only two of said LEDs emit light 840. In a further aspect, the method includes actuating said electrical switch so that the LEDs emit light sequentially 850, one at a time, or two or more at a time. The sequence may or may not be random. In a yet further aspect, the electrical switch is a push-button switch that is actuated by pushing. In another aspect, the embodiment includes pivoting said second housing relative to said first housing up or down up to 25 degrees each direction 860. In yet another aspect, the method includes attaching a universal mounting apparatus to a mobile vehicle, and attaching said lighting apparatus to said universal mounting apparatus 870.

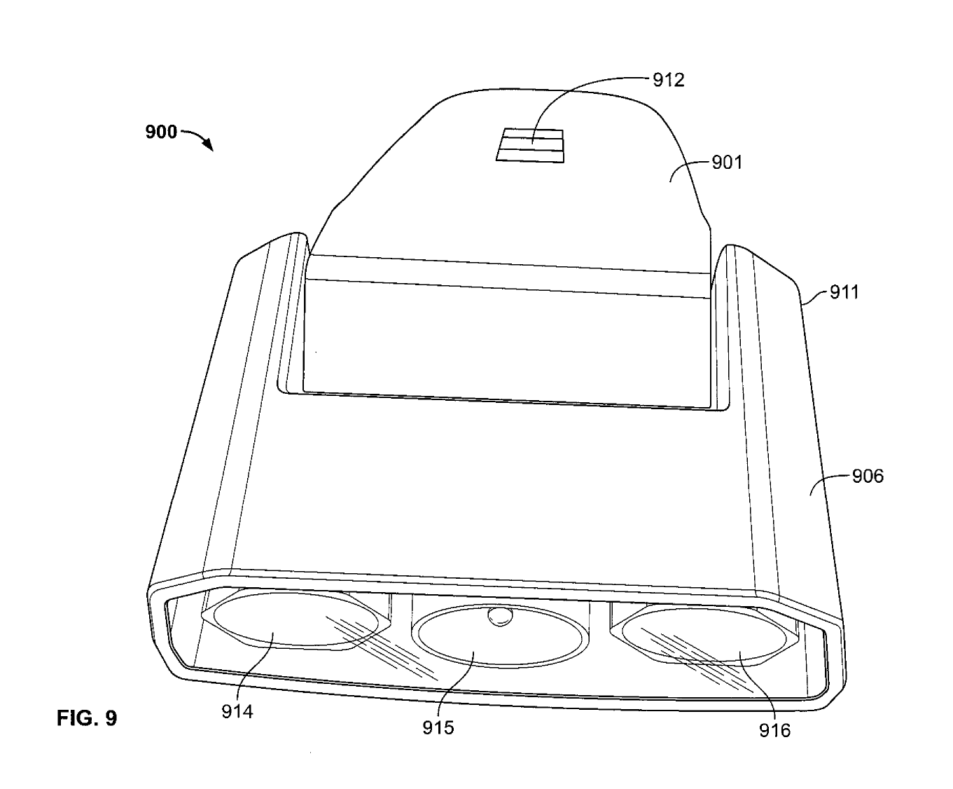

In a further embodiment as shown in FIG. 9, a lighting apparatus 900 configured for use on a mobile vehicle (not shown), comprises a first weatherproof housing 901 including an electrical switch 912, one or more rechargeable batteries (not shown), and a charging outlet (not shown); a second weatherproof housing 906 including three LEDs 914,915,916, wherein at least one of said LED is equipped with a narrow angle beam reflector, at least one of said LED is equipped with a wide angle beam reflector, and the combined light output capacity of the LED is at least 500 lumen; and a weatherproof pivot mechanism 911 that connects the first housing and the second housing and allows the first housing to pivot against the second housing.

In another aspect of the embodiment, the lighting apparatus 900 includes an electrical circuit (not shown) so configured that by actuating said electrical switch 912 the LEDs (914,915,916) operate in various modes including: only one of said LED emits light, only two of said LEDs emit light, and all of said LEDs emit light at the same time. In yet another aspect of the embodiment, the lighting apparatus includes an electrical circuit so configured that by actuating said electrical switch the LED emits light sequentially. In a further aspect of the embodiment, the electrical switch 912 is a push-button switch that is actuated by pushing. In a yet further aspect of the embodiment, the pivot mechanism 911 allows said second housing 906 to pivot relative to said first housing 901 up or down up to 25 degrees in each direction. In another variation of the embodiment, the lighting apparatus 900 further includes a universal mounting apparatus (not shown) for attaching said lighting apparatus to a mobile vehicle (not shown). In yet another variation of the embodiment, the light apparatus is made to be used on a bicycle (not shown).

In another aspect of the embodiment, the LEDs (914,915,916) are shown with a narrow angle beam reflector and wide angle beam reflectors.

Whereas the invention has been described by way of example and in terms of the specific embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A lighting apparatus configured to be used on a mobile vehicle, comprising:
a first housing including a first weatherproof chamber enclosed by an upper horizontal surface, a lower horizontal surface, a rear vertical surface, a front surface, and two side surfaces;
one or more rechargeable lithium ion batteries placed inside said first weatherproof chamber;
a switch on the first housing;
an integral charging port on first housing for recharging said batteries;
a pedestal located on the lower horizontal surface;
a second housing including a second weatherproof chamber, a front vertical surface, a rear faceted surface, and two elongated side arms extending rearward, wherein each arm has an inside face;
two or more LEDs placed inside said second weatherproof chamber, each light emitting diode capable of emitting up to at least 180 lumens;
wherein said switch controls electrical input from said batteries to said LEDs;
a transparent window on the front vertical surface of the second housing;
a pivoting mechanism that connects and allows relative pivotal movement between the first and second housings, wherein said second housing is adjustable to pivot in angles from 25 degrees vertically above to 25 degrees vertically below the horizontal axis of the lighting apparatus; and
a universal mounting apparatus for detachably attaching to said pedestal and to the mobile vehicle.

2. The lighting apparatus according to claim 1, wherein the switch is a push-button switch with a weatherproof cover.

3. The lighting apparatus according to claim 2, wherein the two or more LEDs are capable of operating in a mode selected from the group consisting of: all off, one LED on, two LEDs on, all LEDs on, and a flashing day time mode

4. The lighting apparatus of claim 3, wherein the two or more LEDs are powered on non-simultaneously in the flashing daytime mode.

5. The lighting apparatus according to claim 1, wherein said pedestal is adapted for attaching to the universal mounting apparatus.

6. The lighting apparatus according to claim 5, wherein said pedestal comprises a rectangular column, a first end of said rectangular column attaches to the lower horizontal surface of the first housing, a second end of said rectangular column extends outward to form a base plate, wherein said column has a square cross section.

7. The lighting apparatus according to claim 1, wherein said charging port comprises a micro USB port with a flexible cover.

8. The lighting apparatus according to claim 1, comprising a means for fastening the universal mounting apparatus to the mobile vehicle.

9. The lighting apparatus according to claim 8, wherein the means for fastening comprises a rubber strap.

10. The lighting apparatus according to claim 9, wherein the rubber strap is selected from the group consisting of a small strap, a medium strap and a large strap.

11. The lighting apparatus according to claim 1, wherein the first and second housings are formed of a fusion sealed rigid material.

12. The lighting apparatus according to claim 1, wherein the first housing has a substantially rectangular horizontal cross section that tapers from the front to the rear, forming two side arms, wherein a receiving aperture is formed on the front end of each side surface, wherein the front surface has a outwardly concaved contour;

13. The lighting apparatus according to claim 12, wherein the two side arms of the second housing envelop the first housing, wherein there is a pivot pin on the inside face of each arm, wherein said pivot pins engage the receiving apertures on the first housing.

14. The lighting apparatus according to claim 13, wherein the pivot pins have a hollow tubular structure for conducting electrical wires between the first housing and the second housing.

15. The lighting apparatus according to claim 14, wherein a torque O-ring is fitted over each pivot pin to maintain friction between the first and second housings.

16. The lighting apparatus according to claim 1, wherein the lighting apparatus is adapted to be used on a bicycle.

17. A lighting apparatus configured for use on a mobile vehicle including a universal mounting assembly for interchangeably attaching to a mobile vehicle in one or more mounting configurations, said universal mounting assembly comprising:
a channel assembly with a substantially rectangular rigid body for engaging a pedestal, said channel assembly including:
a recess at the upper surface of the channel assembly bound by a front wall, two side walls, and a bottom plane, wherein the rear of the recess is open, wherein said two side walls are perpendicular to the front wall, wherein each side wall has a rim that forms a groove inside the recess,
a knob protruding on the front face of the channel assembly,
two parallel raised tabs on a bottom surface of the channel assembly,
a rear lower wall on the bottom surface of the channel assembly, said rear lower wall including a substantially rectangular window;
a rubber strap member including a back end block, a middle strap portion, and a front-end block, wherein an elongated cutout extends from the middle strap portion to the front-end block;
wherein the middle strap portion is adapted to pass through the substantially rectangular window;
wherein the elongated cutout is adapted to engage with the knob on the front face of the channel assembly.

18. The lighting apparatus according to claim 17, wherein the front end block is about the same as thick as the middle strap portion, is a little over twice as wide as the center strap portion, and has a rounded curvature on the peripheral of the front end block, and wherein the back end block is wider and thicker than the center strap portion, includes two slits on a first surface for fitting on the two parallel raised tabs on the bottom surface of the channel assembly, and is curved on a second surface for fitting on a tubular object.

19. The lighting apparatus according to claim 18, wherein said bottom plane includes a cutout tab formed between two parallel cutouts, said cutout tab having a raised notch at the rear opening of the recess, said cutout tab extends outside of the recess forming a finger tab.

20. A method of illuminating a mobile vehicle, comprising the steps of:
powering a lighting apparatus by using one or more lithium ion rechargeable batteries;
recharging said batteries with an integral charging port,
illuminating said lighting apparatus by using two or more LEDs each capable of outputting at least 180 lumens;
actuating a switch on said first housing;
controlling electrical input from said batteries to said LEDs and
attaching a pivoting mechanism between a first housing and second housing of the lighting apparatus.

21. A method of illuminating according to claim 20, wherein said pivoting mechanism allows electrical communication between said first and second housings.

22. The method of illuminating according to claim 20, further comprising the step of pivoting said second housing relative to said first housing to provide emission angles up to 25 degrees vertically above and below the horizontal axis of the lighting apparatus.

23. The method of illuminating according to claim 20 wherein the first housing comprises a pedestal for attaching to a mounting apparatus.

24. The method of illuminating according to claim 20, comprising providing a translucent window on a forward vertical surface of the second housing.

25. The method of illuminating according to claim 22, wherein the first and second housings are formed of a rigid material.

26. The method of illuminating according to claim 20, wherein three LEDs are provided.

27. The method of illuminating according to claim 26, wherein the three LEDs are capable of being independently controlled.

28. The method of illuminating according to claim 20, wherein the switch is a push-button switch.

29. The method of illuminating according to claim 20, wherein the mobile vehicle is a bicycle.

30. A method of making a lighting apparatus configured for use on a mobile vehicle, comprising the following steps in any order:
making a first housing including a first weatherproof chamber enclosed by an upper horizontal surface, a lower horizontal surface, a rear vertical surface, a front surface, and two side surfaces;
installing one or more rechargeable lithium ion batteries placed inside said first weatherproof chamber;
providing an integral charging port on said first housing;
providing a pedestal on the lower horizontal surface;
positioning a switch on the first housing;
making a second housing including a second weatherproof chamber and a front vertical surface;
providing a transparent window on the front vertical surface of the second housing;
installing two or more LEDs inside said second weatherproof chamber, each light emitting diode capable of emitting up to at least 180 lumens;
connecting the first housing and the second housing via a pivoting mechanism; and
providing a universal mounting apparatus for detachably attaching said pedestal and to the mobile vehicle.

31. The method of making a lighting apparatus according to claim 30, wherein the pivoting mechanism allows relative pivotal movement between the first and second housings, wherein said second housing is adjustable to pivot in angles from 25 degrees vertically above to 25 degrees vertically below the horizontal axis of the lighting apparatus.

32. The method of making a lighting apparatus according to claim 30, wherein said switch controls electrical input from said batteries to said diodes.

33. The method of making a lighting apparatus according to claim 32, wherein the switch mechanism is a push on-off switch.

34. The method of making a lighting apparatus according to claim 30, wherein said pedestal is adapted for slidably attaching to the universal mounting apparatus.

35. The method of making a lighting apparatus according to claim 30, further comprising a means for fastening the universal mounting apparatus to the mobile vehicle.

36. The method of making a lighting apparatus according to claim 35, wherein the means for fastening comprises a rubber strap.

37. The method of making a lighting apparatus according to claim 36, wherein the rubber strap is selected from the group consisting of a small strap, a medium strap and a large strap.

38. The method of making a lighting apparatus according to claim 30, wherein the first and second housings are formed of a fusion sealed rigid material.

39. The method of making a lighting apparatus according to claim 30, wherein the pivoting mechanism comprises a torque O ring to maintain the second housing at a predetermined configuration.

40. The method of making a lighting apparatus according to claim 30, wherein the three LEDs is capable of operating sequentially.

41. The method of making a lighting apparatus according to claim 40, further comprising a flashing day time mode capable of emitting 180 lumens every 0.75 seconds.

42. The method of making a lighting apparatus according to claim 30, wherein the lighting apparatus is adapted to be used on a bicycle.

43. A method of operating a lighting apparatus, comprising:
charging the lighting apparatus, wherein said lighting apparatus includes a first housing including the electrical switch, one or more rechargeable batteries, and a charging outlet, a second housing including two or more LEDs, and a pivot mechanism connecting the first housing and the second housing and allowing the first housing to pivot against the second housing, wherein at least one of said LEDs is equipped with a narrow angle beam reflector, and wherein at least one of said LEDs is equipped with a wide angle beam reflector; and
turning on said light apparatus by actuating an electrical switch causing electrical power to be supplied to all of one or more LED to output light with a total light output of up to 540 lumens or more.

44. The method of operating a lighting apparatus of claim 43, further comprising actuating said electrical switch so that only one of said LED emits light.

45. The method of operating a lighting apparatus of claim 43, further comprising actuating said electrical switch so that only two of said LED emits light.

46. The method of operating a lighting apparatus of claim 43, further comprising actuating said electrical switch so that the LED emits light sequentially, one at a time.

47. The method of operating a lighting apparatus of claim 43, wherein said electrical switch is a push-button switch that is actuated by pushing.

48. The method of operating a lighting apparatus of claim 43, further comprising pivoting said second housing against said first housing up or down up to 25 degrees each direction.

49. The method of operating a lighting apparatus of claim 43, further comprising attaching a universal mounting apparatus to a mobile vehicle, and attaching said lighting apparatus to said universal mounting apparatus.

50. A lighting apparatus configured for use on a mobile vehicle, comprising:
a first weatherproof housing including an electrical switch, one or more rechargeable batteries, and a charging outlet;
a second weatherproof housing including more than one LED, wherein at least one of said LED is equipped with a narrow angle beam reflector, at least one of said LED is equipped with a wide angle beam reflector, and the combined light output capacity of the LED is at least 500 lumen; and
a weatherproof pivot mechanism that connects the first housing and the second housing and allows the first housing to pivot against the second housing.

51. The lighting apparatus of claim 50, comprising an electrical circuit so configured that by actuating said electrical switch the LED operate in various modes including: only one of said LED emits light, only two of said LED emit light, and all of said LED emit light at the same time.

52. The lighting apparatus of claim 50, comprising an electrical circuit so configured that by actuating said electrical switch so that the LED emits light sequentially.

53. The lighting apparatus of claim 50, wherein said electrical switch is a push-button switch that is actuated by pushing.

54. The lighting apparatus of claim 50, wherein said pivot mechanism allows said second housing pivot relative to said first housing up or down up to 25 degrees in each direction.

55. The lighting apparatus of claim 50, further comprising a universal mounting apparatus for attaching said lighting apparatus to a mobile vehicle.

56. The lighting apparatus of claim 50, wherein said light apparatus is made to be used on a bicycle.
